(19) United States
(12) Patent Application Publication
(10) Pub. No.: US 2008/0068307 A1
(43) Pub. Date: Mar. 20, 2008

(54) GATE AND DATA DRIVERS FOR DISPLAY

(76) Inventor: Kazuyoshi Kawabe, Yokohama (JP)

Correspondence Address: Frank Pincelli;Patent Legal Staff, Eastman Kodak Company, 343 State Street, Rochester, NY, 14650-2201, US

(21) Appl. No.: 11/850,207

(22) Filed: Sep. 5, 2007

(30) Foreign Application Priority Data
Sep. 15, 2006 (JP) 2006-251662

(51) Int. Cl. G09G 3/30

(52) U.S. Cl. 345/80; 345/76

(57) ABSTRACT

A display device including a display array comprising a plurality of pixels arranged in a matrix and, in each pixel, a self-emissive element, a first transistor which controls a supply of electric current contributing to light emission of the self-emissive element, and a second transistor which controls a supply of data voltage to a gate terminal of the first transistor, in which a gate line which supplies a selected voltage to a gate terminal of the second transistor, a data line which supplies the data voltage to a drain terminal of the second transistor, and a power line which supplies a current to the first transistor are arranged along a row or a column of the pixels; a gate driver which drives the gate line; a data driver which drives the data line; and wherein the data line and the power line are formed in different layers.

### CROSS-REFERENCE TO RELATED APPLICATION

This application claims priority of Japanese Patent Application No. 2006-251662 filed Sep. 15, 2006 which is incorporated herein by reference in its entirety.

### FIELD OF THE INVENTION

The present invention relates to an active matrix display device, and more particularly to a control circuit for a display device that includes a self-emissive element.

### BACKGROUND OF THE INVENTION

Recent developments in communication technologies and various information services have introduced portable information devices that offer many advanced functions, such as accessing websites through the Internet and viewing a mobile television, in addition to sending/receiving electronic mails, capturing images or movies, and reproducing music. Furthermore, portable information devices are expected to provide higher usability and enable users to enjoy a greater number of advanced functions.

The liquid crystal display (LCD) has an important role in a portable information device having highly advanced functions. The LCD includes liquid crystals that control the emission of light supplied from a backlight to display a video. According to a driving mechanism of the LCD, the backlight is turned on continuously. In other words, regardless of a video to be displayed, the LCD consumes a constant amount of electric power.

Meanwhile, the organic electroluminescence (EL) display includes organic EL elements (organic light-emitting diodes (OLEDs)) which are self-emissive elements. The organic EL element can provide higher contrast and consumes electric power at a light-emitting portion only. Therefore, when a video is dark, electric power consumption in an organic EL element is low.

In general, the portable information devices are required to be lightweight, thin, and energy efficient. In addition, as discussed above, due to a greater amount of information to be displayed, advanced portable information devices are required to realize a high-resolution and high-definition display.

To realize a high-resolution and high-definition display, pixels of a display device are arranged at narrow pitches. Although no backlight is required, an organic EL display system requires power wiring for supplying current to the pixels. Accordingly, in contrast to the LCD, the organic EL display system needs to secure a region used for the power wiring and cannot easily realize a narrow-pitch layout for the pixels (as discussed in Japanese Patent Application Laid-open No. 2002-196704). To this end, an aperture rate of each pixel is increased so as to realize a narrow-pitch layout. A digital drive organic EL display system is disclosed in, for example, WO 2005/116971.

### SUMMARY OF THE INVENTION

The present invention provides a display device including: a display array including a plurality of pixels arranged in a matrix and, in each pixel, a self-emissive element, a first transistor which controls a supply of electric current contributing to light emission of the self-emissive element, and a second transistor which controls a supply of data voltage to a gate terminal of the first transistor, in which a gate line which supplies a selected voltage to a gate terminal of the second transistor, a data line which supplies the data voltage to a drain terminal of the second transistor, and a power line which supplies a current to the first transistor are arranged along a row or a column of the pixels; a gate driver which drives the gate line; and a data driver which drives the data line, wherein the data line and the power line are formed in different layers.

The data line and gate electrodes of the first and second transistors can be made of the same metal.

Further, the gate line and the power line can also be made of the same metal.

Moreover, preferably, one output terminal of the data driver is connected via switching devices to a plurality of data lines.

Additionally, the data line receives binary data supplied from the data driver to turn on or off the first transistor, and the gate line is selected multiple times during one frame period to control a light emission period of the self-emissive element during one frame period.

In this case, the display device includes a first storage device and a second storage device provided between the switching devices and the data lines, and an output terminal of the data driver supplies data in a time division fashion, wherein the first storage device successively stores the data produced from the output terminal of the data driver at a first timing, and the second storage device outputs the data stored in the first storage device to the plurality of data lines at a second timing.

The present invention can reduce the ratio of a wiring region to a display region. The reduced region can be used to enlarge a light emission region where a self-emissive element is formed. Therefore, the present invention provides a display device having a high-resolution and high-definition display, reducing electric power consumption, and extending the life of each organic EL element.

### BRIEF DESCRIPTION OF THE DRAWINGS

The accompanying drawings, which are incorporated in and constitute a part of the specification, illustrate an embodiment of the invention and, together with the description, serve to explain the principles of the invention, in which:

FIG. 1A is an illustration of a pixel layout according to a first embodiment of the present invention;

FIG. 1B is an illustration of an equivalent circuit of the pixel layout shown in FIG. 1A;

FIG. 2A is a cross-sectional illustration of a drive transistor and an organic EL element;

FIG. 2B is a cross-sectional illustration of a gate transistor;

FIG. 3A is an illustration of a conventional pixel layout;

FIG. 3B is an equivalent circuit of the conventional pixel layout;

FIG. 4A is an illustration of an organic EL display system according to a preferred embodiment of the present invention;

FIG. 4B is a drive timing chart of the organic EL display system according to the preferred embodiment;

FIG. 5A is an illustration of a digital drive organic EL display system according to a preferred embodiment of the present invention;

FIG. 5B is a drive timing chart of the digital drive organic EL display system;

FIG. 6 is a graph illustrating a relationship between a hold voltage and a current;

FIG. 7A is a cross-sectional illustration of an example of a contact portion and wiring layout;

FIG. 7B is a cross-sectional illustration of another example of a contact portion and wiring layout;

FIG. 7C is a cross-sectional illustration of another contact portion and wiring layout; and

FIG. 8 is an illustration of a pixel layout according to a second embodiment.

### DESCRIPTION OF PREFERRED EMBODIMENTS

Embodiments of the present invention are described below with reference to the drawings.

### First Embodiment

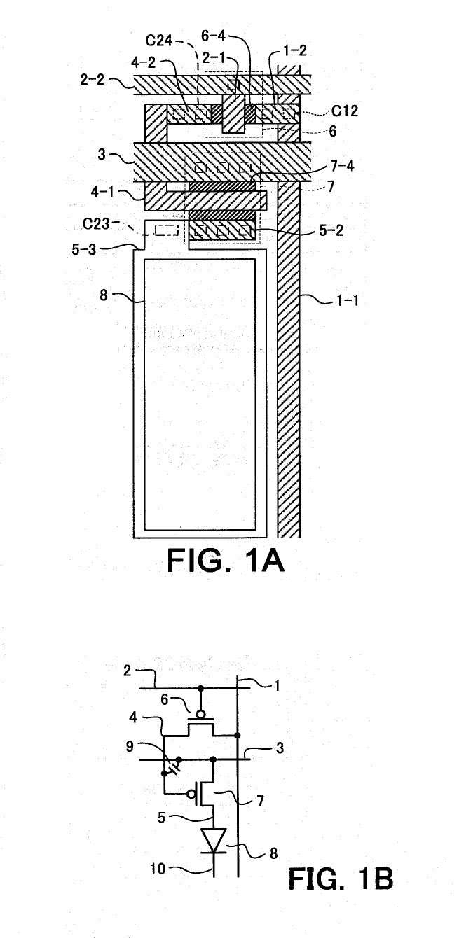

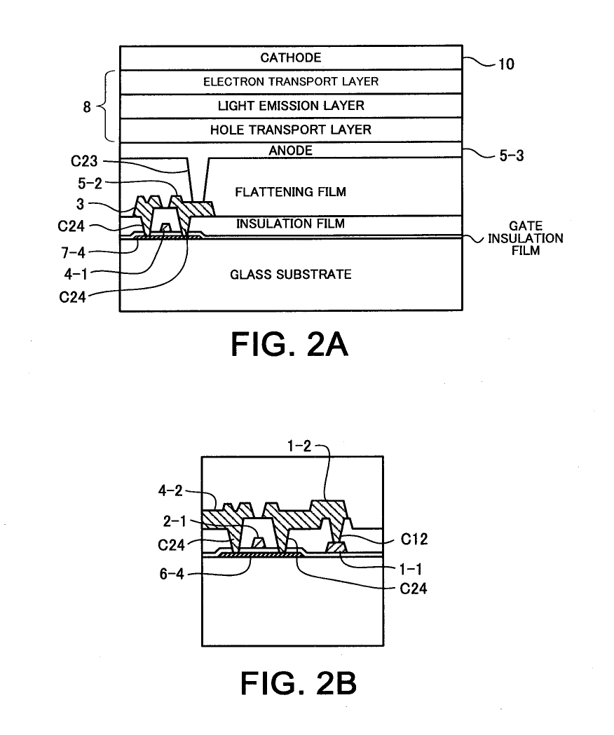

FIG. 1A illustrates a pixel layout according to a first embodiment. FIG. 1B shows an equivalent circuit of the pixel layout shown in FIG. 1A. FIG. 2A is a cross-sectional illustration of the pixel layout shown in FIG. 1A. FIG. 1A corresponds to a plan view of FIG. 2A.

As shown in FIG. 1B, each pixel includes an organic EL element 8, a gate transistor 6 that controls capturing of video data into the pixel, and a drive transistor 7 that drives the organic EL element 8. The gate transistor 6 has a gate terminal connected to a gate line 2, a drain terminal connected to a data line 1, and a source terminal connected to a gate terminal of the drive transistor 7 and to one end of a holding capacitor 9. The drive transistor 7 has its gate terminal connected to the source terminal of the gate transistor 6 and to the one end of the holding capacitor 9, its drain terminal connected to an anode of the organic EL element 8, and its source terminal connected to a power line 3. The other end of the holding capacitor 9 is connected to the power line 3.

According to the example shown in FIGS. 1A and 1B, the data line 1 extends in a column (vertical) direction of the pixel. Both the gate line 2 and the power line 3 extend in a row (horizontal) direction of the pixel. The transistor shown in FIG. 1B is a p-type transistor that can be manufactured simply. However, the transistor of FIG. 1B can be replaced, if desirable, with an n-type transistor.

The data line 1 receives data to be written into the pixel. The gate line 2 supplies, into the holding capacitor 9 of a selected pixel via the gate transistor 6, a signal to control writing of the data. The drive transistor 7 supplies to the organic EL element 8a current or voltage corresponding to the written data. The organic EL element 8 emits light.

The pixel shown in FIGS. 1A and 1B includes three metal layers and one semiconductor layer, in which gate electrodes of the transistors are formed in a first metal layer.

As shown in FIG. 1A, a gate metal 2-1 of the gate transistor 6 and a gate metal 4-1 of the drive transistor 7 are formed in the first metal layer. A data line wiring 1-1 for the data line 1 is formed in the first metal layer. A gate line wiring 2-2 for the gate line 2, the power line 3, a contact metal 1-2 connecting the data line 1 to a drain electrode of the gate transistor 6, a contact metal 4-2 connecting a source electrode of the gate transistor 6 to a gate electrode of the drive transistor 7, and a contact metal 5-2 connecting a drain electrode of the drive transistor 7 to an anode metal 5-3 of the organic EL element 8 are formed in a second metal layer. The anode metal 5-3 of the organic EL element 8 is formed in a third metal layer. A semiconductor island 6-4 of the gate transistor 6 and a semiconductor island 7-4 of the drive transistor 7 are formed in the semiconductor layer.

A contact hole C12 is provided for connection of first and second metals. The second metal layer (upper layer) is connected to the first metal layer (lower layer) via the contact hole C12. The second metal layer (upper layer) is connected to the semiconductor layer (lower layer) via a contact hole C24. The third metal layer (upper layer) is connected to the second metal layer (lower layer) via a contact hole C23. In this manner, contact holes are used for connection of two electrodes and connection of electrodes and wiring.

The data line wiring 1-1, the gate metal 2-1 of the gate transistor 6, and the gate metal 4-1 of the drive transistor 7, which are formed in the first metal layer, are made of the same metal or can be made of different metals. For example, the gate metals 2-1 and 4-1 are made of a first metal. The data line wiring 1-1 can be made of another metal having a low resistance. In the present embodiment, the data line wiring 1-1 and the gate metals 2-1 and 4-1 are made of the same metal.

As shown in FIG. 1A, the gate line 2 disposed in the horizontal direction is connected via a contact hole C12 to the gate metal 2-1 of the gate transistor 6. The data line wiring 1-1 disposed in the vertical direction is connected via the contact hole C12 to the contact metal 1-2. The contact metal 1-2 is connected via the contact hole C24 to the semiconductor island 6-4. The semiconductor island 6-4 forms the drain electrode of the gate transistor 6. The semiconductor island 6-4, forming a source electrode of the gate transistor 6, is connected via the contact hole C24 to the contact metal 4-2. The contact metal 4-2 is connected via the contact hole C12 to the gate metal 4-1 of the drive transistor 7.

The semiconductor island 7-4, forming a source electrode of the drive transistor 7, is connected via the contact hole C24 to the power line 3 disposed in the horizontal direction. The semiconductor island 7-4, forming a drain electrode, is connected via the contact hole C24 to the contact metal 5-2. The contact metal 5-2 is connected via the contact hole C23 to the anode metal 5-3 so as to form the equivalent circuit shown in FIG. 1B.

The holding capacitor 9 is formed in a region where the power line 3 and the gate metal 4-1 overlap each other. The capacitance of the holding capacitor 9 can be increased by increasing an overlap area. For example, the holding capacitor 9 has a large capacitance when most of the gate metal 4-1 is covered with the power line 3.

FIG. 2B is a cross-sectional illustration of the gate transistor 6. The semiconductor island 6-4 is formed on a glass substrate. A gate insulation film covers the semiconductor island 6-4. The gate electrode 2-1 is provided, via the gate insulation film, on a gate region of the semiconductor island 6-4. An insulation film (i.e., interlayer insulation film) covers the gate electrode 2-1.

Paired contact holes C24 and C24 are formed at respective ends (source and drain terminals) of the semiconductor island 6-4 (in the horizontal direction of FIG. 1A), where the contact metal 4-2 functioning as a source electrode and the contact metal 1-2 functioning as a drain electrode are partially formed. The contact holes C24 and C24 extend vertically across the gate insulation film and the interlayer insulation film.

The data line 1-1 and the gate electrode 2-1 are formed in the same layer (i.e., on the gate insulation film). The contact hole C12 is formed on the data line 1-1 where the contact metal 1-2 is partially disposed. The data line 1-1 is connected to the drain terminal of the gate transistor 6.

The other end of the contact metal 4-2 connected via the contact hole C24 to the source terminal of the gate transistor 6 is connected via the contact hole C24 to an extended portion of the gate electrode 4-1 of the drive transistor 7.

FIG. 2A is a cross-sectional illustration of the drive transistor 7. The drive transistor 7 is similar in arrangement to the gate transistor 6. The semiconductor island 7-4 is formed on a glass substrate. The gate electrode 4-1 is formed on a gate insulation film covering the semiconductor island 7-4. An interlayer insulation film is formed on the gate electrode 4-1. Paired contact holes (each including three holes according to an example shown in FIG. 1A) C24 and C24 are provided at respective ends (i.e., at the upper and lower sides in FIG. 1A) of the semiconductor island 7-4, where the power line 3 and the contact metal 5-2 are partially disposed.

A flattening film covers the power line 3 and the contact metal 5-2. The contact hole C23 is formed on the contact metal 5-2, in which part of the anode of the organic EL element 8 extends from the upper surface of the flattening film. Organic layers, including a hole transport layer, a light emission layer, and an electron transport layer, are formed on the anode. A cathode 10 is formed on the electronic transport layer. The anode of the organic EL element 8 is a transparent conductor (e.g., ITO). The cathode is made of aluminum or other metal.

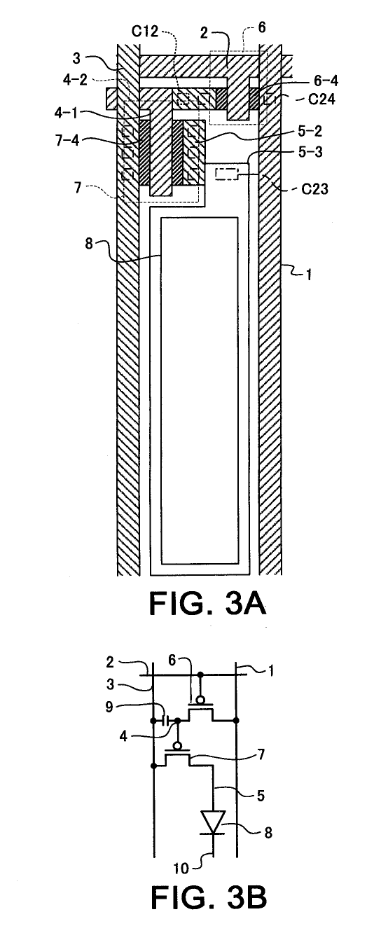

FIG. 3A illustrates a conventional pixel layout. FIG. 3B shows an equivalent circuit of the conventional pixel layout. The equivalent circuit of FIG. 3B is functionally similar to the equivalent circuit of FIG. 1B, although the illustration is modified to a form reflecting the layout.

According to the conventional pixel layout, the gate line 2 is formed in the first metal layer and extends in the horizontal direction. The gate line 2 becomes a gate metal of the gate transistor 6. Both the data line 1 and the power line 3 are formed in the second metal layer and extend in the vertical direction transversely to the gate line 2. The data line 1 is connected via the contact hole C24 to the semiconductor island 6-4. The semiconductor island 6-4 forms the drain electrode of the gate transistor 6.

The connection between the semiconductor island 6-4 forming the source electrode of the gate transistor 6 and the gate metal 4-1 of the drive transistor 7 can be realized in the following manner.

First, the semiconductor island 6-4 forming the source electrode of the gate transistor 6 is connected via the contact hole C24 to the contact metal 4-2. The contact metal 4-2 is connected via the contact hole C12 to the gate metal 4-1. The holding capacitor 9 can be realized by overlapping the power line 3 with the gate metal 4-1. The holding capacitor 9 has a larger capacitance when an overlap area of the power line 3 and the gate metal 4-1 is large.

The semiconductor island 7-4 forming the source electrode of the drive transistor 7 is connected via the contact hole C24 to the power line 3. The semiconductor island 7-4 forming the drain electrode is connected via the contact hole C24 to the contact metal 5-2. The contact metal 5-2 is connected via the contact hole C23 to the anode metal 5-3.

The above-mentioned conventional pixel layout requires, for one pixel, one pathway extending in the horizontal direction as the first metal wiring and two pathways extending in the vertical direction as the second metal wiring. Thus, to realize the resolution of QVGA (240 pixels in the horizontal direction and 320 lines in the vertical direction) for a full color display of red (R), green (G), and blue (B), the conventional pixel layout requires 320 pathways extending in the horizontal direction as the first metal wiring and 1440 (=240×3×2) pathways extending in the vertical direction as the second metal wiring. The number of required wiring pathways totals 1760.

As is apparent from FIGS. 1A and 1B, for the same number of pixels, the pixel layout of the present embodiment requires 720 (=240×3) pathways extending in the vertical direction as the first metal wiring and 640 (=320×2) pathways extending in the horizontal direction as the second metal wiring. The number of required wiring pathways totals 1360. Thus, the present embodiment can reduce a wiring region occupied in a display region. The region not used for the wiring can be used to enlarge a light emission region where organic EL elements are formed. Therefore, the present embodiment can lower electric power consumption and can extend the life of each organic EL element.

The total number of sub-pixels forming one pixel is not limited to three (i.e., RGB colors). For example, a pixel can include a total of four sub-pixels dedicated to RGB colors and white color.

In general, white color is frequently used in the display. Therefore, using one sub pixel for exclusively producing white color is useful in an organic EL display system. A full color organic EL display system using white color organic ELs can use color filters to produce RGB colors. The RGB pixel, having no sub-pixel dedicated to white color, turns on all of RGB sub-pixels to produce white color. However, the white color light produced through color filters has lower light emission efficiency due to absorption in the color filters. Accordingly, RGB sub pixels consume a relatively large amount of current. As a result, electric power consumption increases, and the life of each element becomes shorter.

On the other hand, if a pixel includes a sub-pixel dedicated to white color (i.e., W sub pixel), other sub-pixels (i.e., RGB sub pixels) do not frequently turn on to produce the white color. Thus, electric power consumption is decreased, and the life of each element can be extended.

However, when one pixel (i.e., a W sub-pixel) is added, a pixel pitch becomes smaller and the conventional layout cannot assure a sufficient aperture rate. According to the above-mentioned example, the conventional layout requires 320 pathways extending in the horizontal direction as the first metal wiring and 1920 (=240×4×2) pathways extending in the vertical direction as the second metal wiring. The number of required pathways totals 2240.

On the other hand, the pixel layout of the present embodiment requires 960 (=240×4) pathways extending in the vertical direction as the first metal wiring and 640 (=320×2) pathways extending in the horizontal direction as the second metal wiring. The number of required pathways totals 1600.

For example, a display screen may be required to realize the resolution of VGA (480 pixels in the horizontal direction and 640 lines in the vertical direction). In this case, the pixels are disposed at finer pitches. As compared to the conventional layout, the pixel layout according to the present embodiment can provide a sufficient area for light emission.

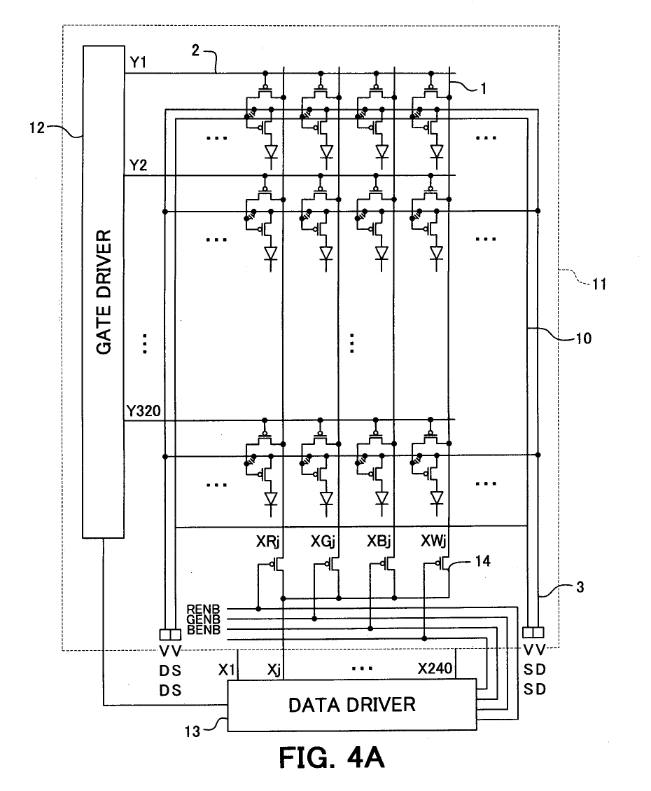

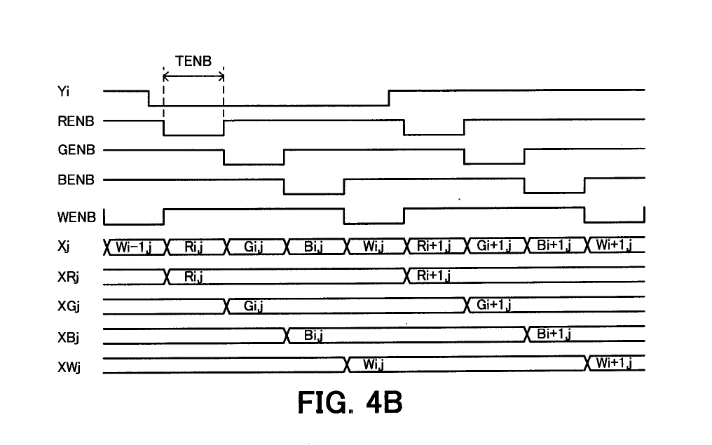

FIG. 4A illustrates an organic EL display system 11 including RGBW sub-pixels according to the present embodiment. The organic EL display system 11 includes a pixel array of numerous pixels disposed in a matrix pattern on a glass substrate. Each pixel has the arrangement shown in FIGS. 1A and 1B.

Both a gate driver 12 and a data driver 13, if fabricated from a low-temperature poly-silicon thin film transistor (TFT), can be formed on the glass substrate. However, the example shown in FIG. 4A forms only the gate driver 12 on the glass substrate. Namely, both the pixel array and the gate driver 12 are fabricated from low-temperature poly-silicon TFTs. An external integrated circuit (IC) provides the function of the data driver 13.

The data driver 13 has 240 output terminals each connected via selection switches 14 to RGBW data lines so that one output can be commonly used by the RGBW sub-pixels. As described later, the data driver 13 can output RGBW data in a time division fashion to the RGBW data lines.

A constant voltage VDD is supplied to the power line 3 that is commonly used for all pixels disposed in a matrix pattern. A constant voltage VSS is supplied to the cathode 10 of the organic EL element 8 of each pixel. Employing a symmetric arrangement for supplying voltages VDD and VSS from both sides as shown in FIG. 4A is desirable for uniformly supplying the voltages VDD and VSS to all pixels. It is, however, possible to employ an asymmetric arrangement for supplying the voltages VDD and VSS from only one side (left or right side). According to the latter arrangement, the lateral wiring length becomes shorter if a vertical size is longer than a lateral size.

A method for driving data lines XRj, XGj, XBj, and XWj of RGBW sub pixels of j-th column shown in FIG. 4A is described below with reference to a timing chart of FIG. 4B. FIG. 4B illustrates timing for writing RGBW data into respective RGBW sub-pixels of i-th row/j-th column pixel. First, the gate driver 12 turns a gate line Yi of i-th row to a low level. The gate transistor of i-th row pixel is opened. Next, the selection switches 14 connecting a j-th output terminal Xj of the data driver 13 to RGBW sub-pixels are successively closed in response to RENB, GENB, BENB, and WENB enable control signals. The output terminal Xj of the data driver 13 successively outputs R data Ri,j, G data Gi,j, B data Bi,j, and W data Wi,j to the i-th row/j-th column pixel in synchronism with RENB, GENB, BENB, and WENB enable control signals.

At this moment, the data lines XRj, XGj, XBj, and XWj of RGBW sub-pixels already store the data of the previous (i-1)-th line.

In response to the aforementioned enable control signals and a supply of data, the data line XRj receives R data Ri,j at the RENB enable timing. The data line XGj receives G data Gi,j at the GENB enable timing. The data line XBj receives B data Bi,j at the BENB enable timing. The data line XWj receives W data Wi,j at the WENB enable timing. When the data writing to the RGBW data lines has completed and the state of the data is stabilized, the gate driver 12 turns the gate line Yi of i-th row to a high level to close the gate transistor of the i-th row pixel. The written data are stored in the pixel until the next time the pixel is accessed.

The written data can be analog data having multiple voltage levels, or digital data having binary voltage levels.

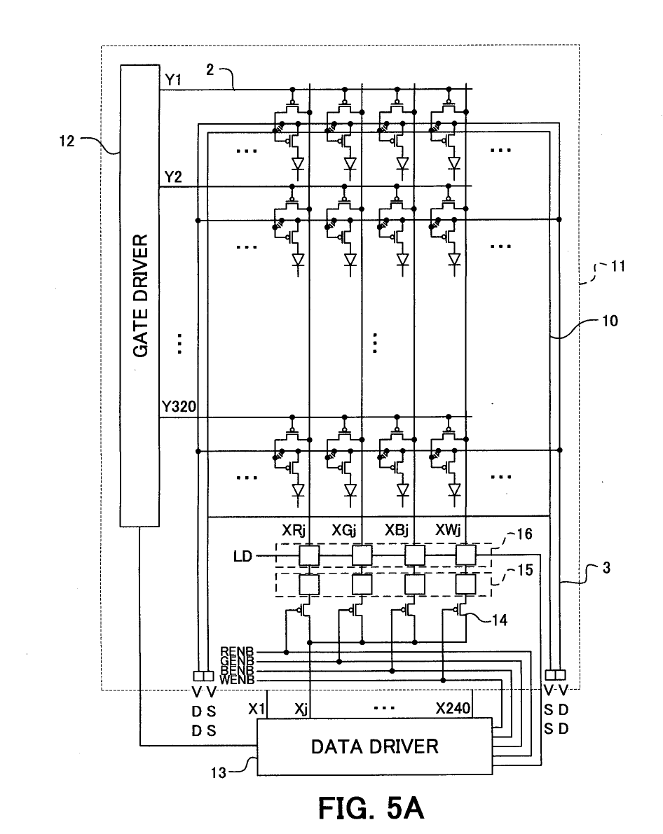

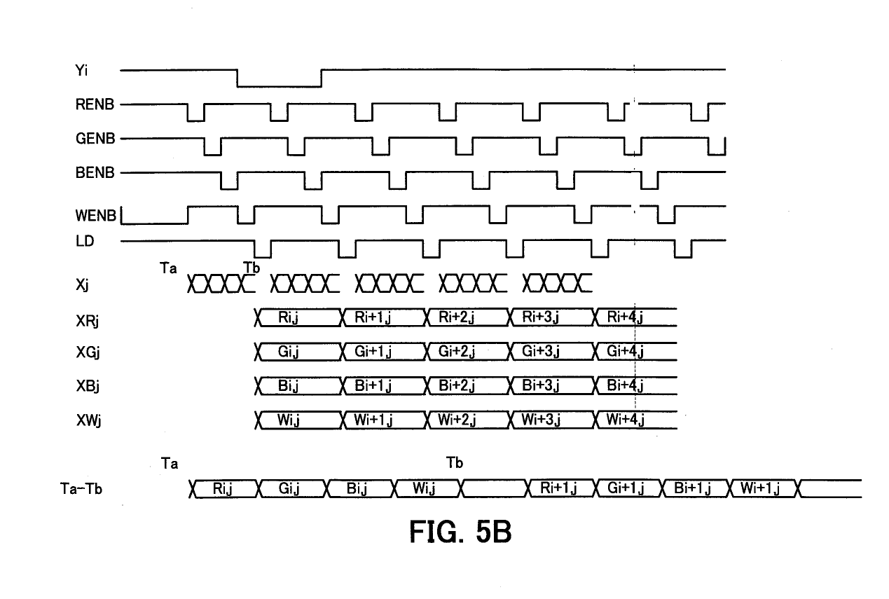

A digital drive display system supplies digital data to turn on and off an organic EL element so as to control the gradation on the basis of a light emission period (refer to Japanese Patent Application Laid-open No. 2005-331891). Each pixel is accessed multiple times during one frame period. FIGS. 5A and 5B illustrate an example of the digital drive display system preferably applied to quickly drive the data lines XRj, XGj, XBj, and XWj.

The circuit arrangement of FIG. 5A includes a first latch circuit 15 and a second latch circuit 16 in addition to the aforementioned arrangement of the display system shown in FIG. 4A. A method for driving the data lines XRj, XGj, XBj, and XWj is described below with reference to the timing chart of FIG. 5B.

The output terminal Xj of the data driver 13 outputs digital data to write RGBX data into an i-th row/j-th column pixel. The selection switches 14 are successively closed in synchronism with RENB, GENB, BENB, WENB enable control signals to input the digital data into the first latch circuit 15. In this case, the first latch circuit 15 can receive RGBW digital data Ri,j, Gi,j, Bi,j, and Wi,j for the i-th row/j-ith column pixel during a period of timing Ta-Tb.

At the timing the gate driver 12 next turns the gate line Yi of i-th row to a low level, the first latch circuit 15 transfers the captured digital data Ri,j, Gi,j, Bi,j, and Wi,j to the second latch circuit 16 simultaneously in response to an LD signal. Then, the digital data Ri,j, Gi,j, Bi,j, and Wi,j are output to the data lines XRj, XGj, XBj, and XWj. When the state of RGBW data simultaneously supplied to the data lines is stabilized, the gate driver 12 turns the gate line Yi to a high level. The gate transistors of the i-th row are turned off. The written data are stored in the pixel of the i-th row until the next time the pixel is accessed.

In the display system shown in FIGS. 4A and 4B, the data driver 13 directly drives the data lines XRj, XGj, XBj, and XWj. On the other hand, the digital drive display system shown in FIGS. 5A and 5B drives the data lines XRj, XGj, XBj, and XWj with the second latch circuit 16 formed in the organic EL display system 11.

When the data driver 13 directly drives the data lines as shown in FIGS. 4A and 4B, a delay of signal occurs in each data line because of a parasitic capacitance or resistance. In particular, the metal wiring for the gate metal has a large wiring resistance. Thus, a significant time (i.e., enable period TENB) is required before the state of data is stabilized. In other words, as shown in FIG. 4B, the writing operation of one line requires 4×TENB, because the delay of signal is repeated for respective RGBW data lines.

According to the digital drive display system shown in FIGS. 5A and 5B, the data driver 13 is required to transfer the data to the first latch circuit 15. The signal delay in this case is negligible if the metal wiring pathway has a low resistance and a small capacitance. Thus, the data transfer can be accomplished within a short time.

It is now assumed that TENB′ (=TENB/5) represents an enable period in the digital drive display system. If the data is simultaneously transferred from the first latch circuit 15 to the second latch circuit 16 in a period of TENB′, the time required for driving the data lines is 4×TENB′+TENB′=TENB. In other words, the digital drive display system shown in FIGS. 5A and 5B can drive the data lines at a speed four times that of the display system shown in FIGS. 4A and 4B.

According to the conventional layout, TENB is relatively short, because the data line is made of aluminum or other low-resistance metal serving as the second metal wiring. Thus, the conventional layout can quickly drive the data lines.

On the other hand, according to the layout of the present embodiment, the data line is made of the first metal used for the gate metal which is generally made of chrome or molybdenum or other metal having relatively high resistance. Accordingly, TENB becomes longer due to wiring delay. In this respect, the conventional layout cannot be employed for a digital drive display system.

Employing the arrangement and driving method shown in FIGS. 4A and 4B is useful for quickly driving the data lines and attaining a higher aperture rate. Thus, the display system of FIGS. 4A and 4B can be effectively used for a digital drive display system.

Using the digital drive display system brings the following effects.

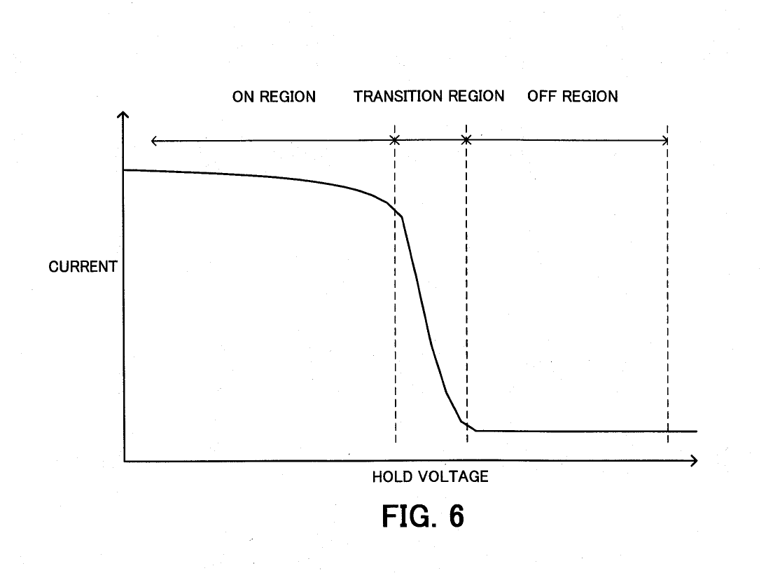

FIG. 6 is a graph illustrating a relationship between a gate voltage applied to the drive transistor 7; i.e., a voltage written into the holding capacitor 9 (X-axis) and a current flowing in the organic EL element 8 (Y-axis). FIG. 6 shows three regions: i.e., an OFF region, a transition region, and an ON region. When the voltage written into the holding capacitor 9 is higher than a first level, the organic EL element 8 is in an off state (i.e., the OFF region). When the voltage written into the holding capacitor 9 is between the first level and a second level which is lower than the first level, the current starts flowing and increases if the voltage level decreases (i.e., the transition region). When the voltage written into the holding capacitor 9 is lower than the second level, the current is saturated (i.e., the ON region).

When an analog voltage is written into the holding capacitor 9, the drive transistor 7 supplies to the organic EL element 8 a current corresponding to the analog voltage. In this case, the current supplied to the drive transistor 7 varies in the transition region shown in FIG. 6. In the transition region, the current value changes greatly if the voltage written into the holding capacitor 9 changes slightly. To effectively suppress a voltage change, the holding capacitor 9 preferably has a relatively large capacitance so that a leakage current can be reduced or a voltage change caused by a parasitic capacitance can be suppressed. However, if the holding capacitor 9 has a large capacitance, a region occupied by the capacitor 9 increases and a light emission region decreases in a pixel portion.

On the other hand, a digital drive display system uses only two regions (i.e., an OFF region and an ON region) to control a supply of current to the organic EL element 8. The voltage ranges defining the OFF region and the ON region; i.e., a voltage range for completely turning off the organic EL element 8 and a voltage range for turning on the organic EL element 8, can be strongly differentiated.

Thus, even if a voltage change occurs due to leakage current or parasitic capacitance, the state of each pixel does not change from an OFF state to an ON state, or vice versa. As the current is saturated in an ON state of the pixel, the current value does not change in response to a voltage change.

Moreover, according to a digital drive display system, a pixel receives digital data multiple times during one frame period and accordingly the holding characteristic of a holding capacitor is not as important as in the case of writing of analog voltages. In other words, the size of the holding capacitor 9 can be reduced and a light emission region can be increased.

Employing the pixel layout shown in FIGS. 1A and 1B for a digital drive display system can maximize a light emission region of the organic EL element, reduce electric power consumption, extend the life of each element, and realize a high-definition display.

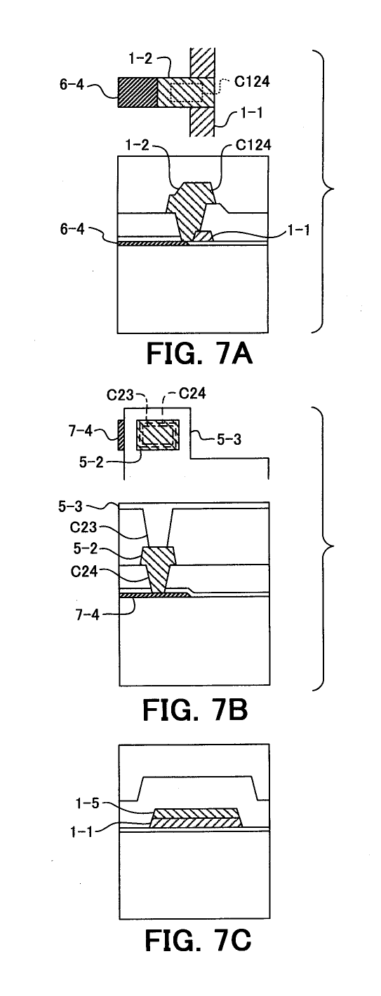

Moreover, examples shown in FIGS. 7A, 7B, and 7C can be used to provide a large aperture.

According to an example shown in FIG. 7A, a contact hole C124 connects a first metal and a semiconductor layer with a contact metal made of a second metal. The data line wiring 1-1 is connected via a contact metal 1-2 to the semiconductor island 6-4 that forms a drain electrode of the gate transistor 6.

To minimize a contact area, it is useful to dispose the data line wiring 1-1 and the semiconductor island 6-4 sufficiently close to each other and form a contact hole having a width capable of connecting the data line wiring 1-1 and the semiconductor island 6-4. In this case, the data line wiring 1-1 and the semiconductor island 6-4 can be overlapped.

According to an example shown in FIG. 7B, the semiconductor island 7-4 forming the drain electrode of the drive transistor 7 is connected via contact holes C23 and C24 to the anode metal 5-3. The contact holes C23 and C24 are successively disposed in the vertical direction.

Combining the arrangement of FIG. 7A or 7B with the layout of FIG. 1A can assure a large aperture.

According to an example shown in FIG. 7C, a metal 1-5 made of aluminum or other low-resistance material is formed on the data line wiring 1-1. According to the multilayered metal wiring example shown in FIG. 7C, a large wiring delay is caused if the data line is made of the first metal having a relatively high resistance. In this respect, disposing a low-resistance metal layer is effective for lowering the wiring resistance. When a display size is large, the wiring length becomes longer and a long wiring delay is caused. Thus, the wiring arrangement using multilayered low-resistance metals can be preferably applied to various display sizes.

### Second Embodiment

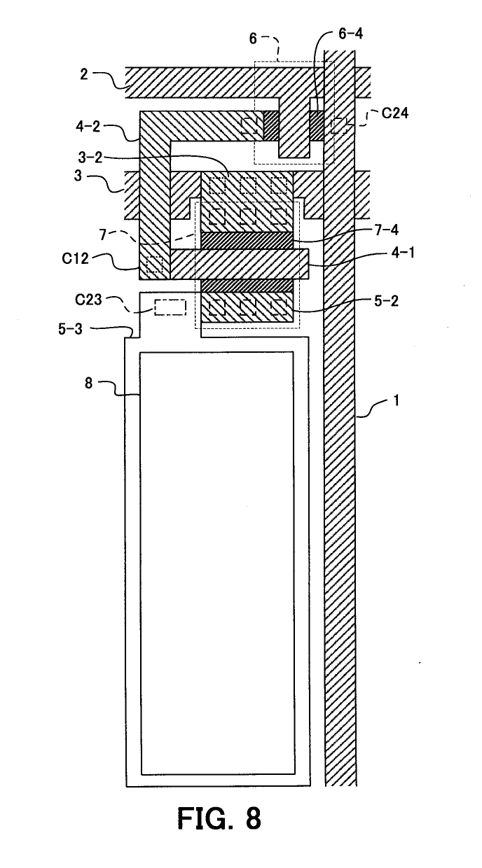

The first embodiment has described the pixel layout that can be fabricated by manufacturing processes compatible with the manufacturing processes for a low-temperature poly-silicon TFT that are conventionally employed for LCDs. However, if in the future the manufacturing processes for a low-temperature poly-silicon TFT can be improved to allow widespread use of the organic EL display, a pixel layout shown in FIG. 8 can be employed to effectively increase the aperture rate. Although not shown in the drawings, an equivalent circuit of the pixel layout shown in FIG. 8 is similar to that shown in FIG. 1B.

According to the pixel layout shown in FIG. 8, the power line 3 is formed in the first metal layer. The layout of FIG. 8 is preferably employed if low-resistance material (e.g., aluminum or copper) can be used for a gate metal forming a gate electrode when the manufacturing processes are improved.

Namely, when the gate metal is made of a low-resistance material, the gate metal can supply a sufficient amount of current and therefore can be used as the wiring for the power line 3.

The data line 1 vertically extends transversely to the gate line 2 and the power line 3, which are parallel to each other and extend in the horizontal direction. The data line 1 and contact metals 4-2, 3-2, and 5-2 are formed in the second metal layer. The data line 1 is connected via the contact hole C24 to the semiconductor island 6-4 forming the drain electrode of the gate transistor 6.

The semiconductor island 6-4 forming the source electrode of the gate transistor 6 is connected via the contact hole C24 to the contact metal 4-2. The contact metal 4-2 is connected via the contact hole C12 to the gate metal 4-1 of the drive transistor 7. The contact hole C24 connects the semiconductor island to the second metal layer. The contact hole C12 connects the first metal layer to the second metal layer.

The semiconductor island 7-4 forming the source electrode of the drive transistor 7 is connected via the contact hole C24 to the contact metal 3-2. The contact metal 3-2 is connected via the contact hole C12 to the power line 3. The semiconductor island 7-4 forming the drain electrode is connected via the contact hole C24 to the contact metal 5-2 and connected via the contact hole C23 to the anode metal 5-3. Thus, the pixel having the equivalent circuit shown in FIG. 1B can be formed.

According to the layout shown in FIG. 8, the data line 1 is formed in the second metal layer. The wiring formed in the second metal layer can be made of aluminum or other low-resistance metal. Thus, the layout shown in FIG. 8 can lower the wiring resistance of the data line 1. When an organic EL display system has a large screen, the data line 1 has a long wiring length. Accordingly, both a wiring capacitance and a wiring resistance increase. Thus, using the layout of FIG. 8 can suppress the wiring resistance of the data line 1.

Furthermore, if the driving method described in the first embodiment is employed for the pixel circuit of the second embodiment, the organic EL display system can be effectively formed.

The invention has been described in detail with particular reference to certain preferred embodiments thereof, but it will be understood that variations and modifications can be effected within the spirit and scope of the invention.

### PARTS LIST

1 data line
1-2 contact metal
1-1 data line wiring
1-5 metal
2 gate line
2-1 gate metal
2-2 gate line wiring
3 power line
3-2 contact metal
4-1 gate metal
4-2 contact metal
5-2 contact metal
5-3 anode metal
6 gate transistor
6-4 semiconductor island
7 drive transistor
7-4 semiconductor island
8 organic EL element
9 holding capacitor
10 cathode
11 organic EL display system
12 gate driver
13 data driver
14 selection switches
15 first latch circuit

### PARTS LIST CONT'D

16 second latch circuit
C12 contact hole
C23 contact hole
C24 contact hole
C124 contact hole

1. A display device comprising:
a display array comprising a plurality of pixels arranged in a matrix and, in each pixel, a self-emissive element, a first transistor which controls a supply of electric current contributing to light emission of the self-emissive element, and a second transistor which controls a supply of data voltage to a gate terminal of the first transistor, in which a gate line which supplies a selected voltage to a gate terminal of the second transistor, a data line which supplies the data voltage to a drain terminal of the second transistor, and a power line which supplies a current to the first transistor are arranged along a row or a column of the pixels;
a gate driver which drives the gate line;
a data driver which drives the data line; and
wherein the data line and the power line are formed in different layers.

2. The display device according to claim 1, wherein the data line is formed in the same layer with a layer which forms gate electrodes of the first and second transistors, and the gate line and the power line are formed in layers which differ from that of the data line and are transverse to the data line.

3. The display device according to claim 1, wherein the power line is formed in the same layer with a layer which forms gate electrodes of the first and second transistor, and the data line is transverse to the power line and is formed in a different layer.

4. The display device according to claim 2, wherein the data line and the gate electrodes of the first and second transistors are made of the same metal.

5. The display device according to claim 2, wherein the gate line and the power line are made of the same metal.

6. The display device according to claim 1, wherein one output terminal of the data driver is connected via switching devices to a plurality of data lines.

7. The display device according to claim 1, wherein the data line receives binary data supplied from the data driver to turn on or off the first transistor, and the gate line is selected multiple times during one frame period to control a light emission period of the self-emissive element during one frame period.

8. The display device according to claim 6, wherein the display device includes a first storage device and a second storage device provided between the switching devices and the data lines, and an output terminal of the data driver supplies data in a time division fashion, wherein the first storage device successively stores the data produced from the output terminal of the data driver at a first timing, and the second storage device outputs the data stored in the first storage device to the plurality of data lines at a second timing.
